(19) United States
(12) Patent Application Publication
(10) Pub. No.: US 2008/0107876 A1
(43) Pub. Date: May 8, 2008

(54) Zinc Oxide Microstructures and a Method of Preparing the Same

(75) Inventors: Gyu-chul Yi, Kyungbuk-do (KR); Yong-jin Kim, Kyungbuk-do (KR); Chul-ho Lee, Kyungbuk-do (KR)

Correspondence Address: INTELLECTUAL PROPERTY LAW GROUP LLP, 12 SOUTH FIRST STREET, SUITE 1205, SAN JOSE, CA, 95113, US

(73) Assignees: POSTECH FOUNDATION, Kyungbuk-do (KR); POSTECH ACADEMY-INDUSTRY FOUNDATION, Kyungbuk-do (KR)

(21) Appl. No.: 11/692,161

(22) Filed: Mar. 27, 2007

(30) Foreign Application Priority Data
Mar. 27, 2006 (KR) 10-2006-0027425

(51) Int. Cl. C30B 25/00; B32B 3/10

(52) U.S. Cl. 428/201; 117/106; 117/95

(57) ABSTRACT

Disclosed herein is a method of selectively growing zinc oxide microstructures and the zinc oxide microstructures prepared using the method. The method includes the steps of applying an organic material or an inorganic material on a substrate, forming a pattern having a predetermined specific location and a predetermined interval on the substrate using a physical or chemical etching method, and selectively growing zinc oxide microstructures at the location where the pattern is formed using various growth methods such as hydro-thermal synthesis, physical vapor deposition, chemical vapor deposition method or the like.

### CROSS-REFERENCE TO RELATED APPLICATION

This application claims priority to Korean application no. 10-2006-0027425, filed Mar. 27, 2006, which is hereby incorporated by reference for all purposes.

### BACKGROUND OF THE INVENTION

1. Field of the Invention

The present invention relates to a method of selectively growing zinc oxide microstructures and the zinc oxide microstructures prepared using the method, and, more particularly, to a method of selectively growing zinc oxide microstructures, which includes the steps of applying an organic material or an inorganic material on a substrate, forming a pattern having a predetermined specific location and a predetermined interval on the substrate using a physical or chemical etching method, and selectively growing zinc oxide microstructures at the location where the pattern is formed using various growth methods such as hydro-thermal synthesis, physical vapor deposition, chemical vapor deposition and the like, and to the microstructures prepared using the method.

2. Description of the Related Art

Recently, research into the manufacture of semiconductor devices, photonic devices and memory devices using the electrical, optical and magnetic properties of nanomaterial has been conducted. In order to manufacture these devices using the nanomaterial, technologies for growing the nanomaterial at a desired location are required. In conventional technologies, these devices have been realized using a top-down method of growing a semiconductor thin film and leaving the structure thereof at a desired location through an etching process in order to manufacture these devices using the nanomaterial. However, when the semiconductor thin film is etched through this method, there is a problem in that the physical and chemical damage to deposited material due to the processes cannot be prevented, thereby inhibiting the realization of an active photonic device, such as a laser.

Owing to this problem with the top-down method, a bottom-up method of selectively growing a nanomaterial has been researched and developed. The bottom-up method, which is different from the conventional top-down method in basic principle, has an advantage in that a desired material can be grown in a desired region in a desired form without performing an etching process. As typical examples of the bottom-up method, there are methods of growing a desired material only on a catalyst using a metal catalyst and methods of growing a desired material in a selected region of a substrate, in which patterns are formed, using the difference in selective growth between the desired material and a template, without using the metal catalyst.

For example, a method of growing a nanomaterial using the metal catalyst, which is a method known to have been performed by the Samuelson study group of Lund University, in Sweden, is a method of growing a nanomaterial only on the metal catalyst using a growth method known as a VLS (Vapor-Liquid-Solid) growth method in a chemical vapor deposition method or a physical vapor deposition method. In the method, the nanomaterial is selectively grown only on the metal catalyst through a mechanism such as adsorption or diffusion of a precursor of a material which will be synthesized on the metal catalyst using MOVPE (Metal-Organic Vapor Phase Epitaxy) or CMBE (Chemical Molecular Beam Epitaxy). In particular, in order to grow a nanomaterial oriented vertically or in a certain direction, the nanomaterial can be epitaxially grown by limiting the metal catalyst to a desired region of a suitable substrate using photo-etching or electron beam etching, and then applying the above process thereto.

In this VLS method, since the liquid metal catalyst grows vapor chemical precursors into a desired nanomaterial through a solid-solution treatment or a precipitation process at eutectic temperatures, the nanomaterial can be selectively grown only at the location where the metal catalyst exists. Accordingly, in the VLS method, since the metal catalyst forms a nanomaterial at a high temperature, at which the metal catalyst can exist in a solid state, the contamination of the nanomaterial by the metal catalyst cannot be prevented during the processes. Furthermore, in the VLS method, since high temperature processes are required, a process of combining the metal catalyst with polymer or metal having a low melting point cannot be applied. Further, a metal catalyst having a uniform size must be manufactured in order to grow the nanomaterial such that the diameter and length thereof is uniformly increased. However, there are problems in that the method of adjusting the diameter and length of the nanomaterial is extremely difficult, and the range of metals that can be used as a catalyst is limited.

Meanwhile, in the method of growing the nanomaterial without using a metal catalyst, selective growth properties, by which the nanomaterial grows on some substrates and does not grow on other substrates under specific growth conditions, are used. That is, a nanomaterial layer which does not grow is deposited on a substrate on which the nanomaterial grows under specific conditions, a substrate having a pattern is formed by etching a desired portion of the nanomaterial layer, and thus the nanomaterial is selectively grown only on the substrate exposed to the patterned portion. The representative study group researching this selective growth of nanorods is the Fukui study group of the Hokkaido University in Japan. Here, nanomaterials such as nanorods are grown in a selected region using Metal-Organic Vapor Phase Epitaxy (MOVPE).

This method has an advantage in that no catalyst is used, but has problems in that it is almost impossible to grow a multicomponent material, and only a material which can be grown using the MOVPE is applied. Furthermore, this method also has problems in that processes are complicated because a layer selectively growing under predetermined conditions must be further deposited on a substrate in order to grow a nanomaterial on the patterned substrate without using a metal catalyst, and manufacturing costs are increased because the process temperature is high. In particular, since a material that allows the desired nanomaterial to selectively grow under specific conditions is required, the range of useful materials is limited.

In the above selective growth method, since high quality nanomaterial is prepared using chemical vapor deposition or physical vapor deposition, generally, expensive equipment and high-vacuum and high-temperature growth procedures are required. In particular, since a chamber that can maintain a high vacuum is limited in the size thereof, it is technically difficult to grow nanorods on a surface having a large area.

### SUMMARY OF THE INVENTION

Accordingly, the present invention has been made in order to solve the above problems occurring in the prior art, and an object of the present invention is to provide a method of selectively growing zinc oxide microstructures and the zinc oxide microstructures prepared using the method, and, more particularly, a method of selectively growing zinc oxide microstructures, which includes the steps of applying an organic material or an inorganic material on a substrate, forming a pattern having a predetermined specific location and a predetermined interval on the substrate using a physical or chemical etching method, and selectively growing zinc oxide microstructures on the location where the pattern is formed using various growth methods such as hydro-thermal synthesis, physical vapor deposition, chemical vapor deposition and the like, and the microstructures prepared using the method.

According to the present invention, compared to the conventional method of selectively growing a microstructure, the process thereof is relatively simple, it is possible to control the selective growth of the nanomaterial, having a desired shape, length and diameter at a desired location over a large area, at a desired interval, and at a low temperature, and thus a semiconductor device can be easily manufactured using the microstructure.

Specifically, the present invention provides a method of preparing a microstructure including the steps of coating a substrate with an organic material such as an electron beam resist or a photoresist, or an inorganic material such as silicon dioxide (SiO₂) or titanium dioxide (TiO₂); forming a pattern on the substrate at a desired location and a desired interval using a physical or chemical etching method; chemically reacting precursors of a reactant under predetermined reaction conditions through various growth methods such as hydro-thermal synthesis, physical vapor deposition and chemical vapor deposition; and selectively growing zinc oxide microstructures at the location where the pattern, which has a diameter of several tens of nanometers to several micrometers and a length of several micrometers to several tens of nanometers, is relatively uniformly formed by adjusting a shape, diameter and length of the zinc oxide microstructure.

Accordingly, an aspect of the present invention provides a method of preparing zinc oxide microstructures, comprising the steps of (a) applying an organic material or an inorganic material on a substrate; (b) forming a patterned region on the substrate by patterning a layer coated with the organic material or the inorganic material using a lithography process and a physical or chemical etching method; and (c) selectively growing a zinc oxide layer on the patterned regions.

A lithography process is different from an etching process. When an organic material is used, a pattern is formed using only the lithography process without using the additional etching process. In contrast, when an inorganic material is used, the pattern is formed by removing the inorganic material using the additional etching process after the lithography.

As described above, the conventional method of growing a material by depositing the material using MOCVD, PLD or sputtering has problems in that only a material, characterized in that it has high-temperature heat resistance and does not grow into a desired nanomaterial, can be used, and such material is mostly limited to an inorganic material, because a method of selectively growing a nanomaterial without using a metal catalyst is performed through a high-temperature process. In contrast, the present invention has advantages in that a nanomaterial can be grown using an organic material as well as an inorganic material because the nanomaterial is grown through a low-temperature process. The inorganic material used in the present invention may be formed through the above mentioned high-temperature process, but may be also formed by performing spin coating or dip coating and then performing heat treatment at a relatively low temperature. Accordingly, the “coating process” used in the present invention refers to a process of forming a photoresist into a uniform film on a substrate, and is a relatively economical process compared to “a deposition process” requiring a vacuum.

In the present invention, there may be a problem in which a substrate is not vertically oriented due to the crystallographic difference between the substrate and zinc oxide microstructure. Considering the problem, in the present invention, a buffer layer may be formed between the substrate and the zinc oxide to minimize the crystal defect density by decreasing the crystallographic difference between the substrate and zinc oxide microstructure.

Accordingly, an embodiment of the present invention provides a method of preparing zinc oxide microstructures, comprising the steps of (a) growing a buffer layer on a substrate; (b) applying an organic material or an inorganic material on the buffer layer; (c) forming a patterned region on the buffer layer by patterning a layer coated with the organic material or the inorganic material using a lithography process and a physical or chemical etching method; and (d) selectively growing a zinc oxide layer on the patterned regions.

A typical method of depositing a buffer layer on a substrate includes Metal Organic Chemical Vapor Deposition (MOCVD), Molecular Beam Epitaxy (MBE), Hydride Vapor Phase Epitaxy (HVPE), a Pulsed Laser Deposition (PLD), sputtering and the like, but is not limited thereto. Among these methods, in the metal organic chemical vapor deposition, a reaction precursor is introduced into a reactor (MOCVD apparatus) at a predetermined flow rate through an individual line, the reactor is maintained at a suitable pressure and temperature, and the reaction precursor is chemically reacted to form a buffer layer having a target thickness.

In the present invention, since the buffer layer 105 serves to decrease the mismatch between the substrate 100 and a zinc oxide microstructure which will be formed in a subsequent process and serves to reduce the rate of defects occurring at the interface between the substrate and the zinc oxide microstructure, it is preferred that a material, which has crystal characteristics similar to those of the zinc oxide microstructure which will be formed in subsequent process and can be chemically stabilized, be used as the buffer layer. Particularly, it is preferred that a material, which has a crystal structure, a lattice constant or a thermal expansion coefficient identical or similar to that of the zinc oxide microstructure which will be formed in a subsequent process, be used as the buffer layer. More preferably, a material, which has the same crystal structure as the zinc oxide microstructure which will be formed in a subsequent process, or in which the difference of lattice constant between the buffer layer and the zinc oxide layer is 20% or less, may be used as the buffer layer.

Most preferably, the buffer layer may be formed of a GaN film, a ZnO film or a combination film thereof. Typical reaction precursors for forming the GaN film may include, but are not limited thereto, trimethylgallium (TMGa), triethylgallium (TEGa), gallium trichloride (GaCl₃) and the like as a gallium source. Further, the reaction precursor may include, but is not limited thereto, ammonium (NH₃), nitrogen, tertiary butylamine (N(C₄H₉)H₂) and the like as a nitride source gas. Among these, it is preferred that the GaN buffer layer be grown to a thickness of 10 to 40 nm at a temperature of 400 to 800° C. A reaction precursor used for forming the ZnO film may include diethyl zinc (DEZn), dimethyl zinc (DMZn) and the like, without limitation. Oxygen may be used as an oxide source gas, but is not limited thereto. The GaN buffer layer is grown to a thickness of 10 to 40 nm at a temperature of 400 to 600° C. This buffer layer 105 may be selectively used depending on the substrate used, the growth apparatus (MOCVD apparatus) and the growth conditions.

In the present invention, Si, Al₂O₃, GaN, GaAs, ZnO, InP, SiC, glass (Pyrex glass, tin oxide glass), polymers (PET, PP) and the like may be used as a substrate, but the present invention is not limited thereto.

In the above coating step, coating methods commonly used in the related art may be used. However, in the present invention, an organic material which can be applied on a substrate includes a photoresist material, an electron beam resist material, a polymer material and the like, but is not limited thereto. Further, an inorganic material which can be applied on the substrate includes a ceramic material, a semiconductor material and the like, but is not limited thereto.

Here, various typical photoresists, which are sold under the trademarks such as AZ 1470, Shipley 511-A, TOK IP-3400 and Apex-E, may be used as the photoresist material, and the electron beam material includes PMMA, EBR-9, PBS (poly(butene-1-sulphone), ZEP-520, COP, Shipley SAL and the like. Further, the polymer material may unlimitedly include PMMA, PMMA copolymer, EBR-9 (poly(2,2,2-trifluoroethyl-α-chloroacrylate) manufactured by Toray Inc.), PBS (butene-1-sulphone), ZEP-520 (manufactured by Nippon Zeon Co.) AZ5206 (Clariant), COP (epoxy copolymer of glycidyl methacrylate and ethyl acrylate), P (GMA-co-EA), SAL (manufactured by Shipley Inc.) and the like, but is not limited thereto. Meanwhile, the inorganic material preferably includes SiO₂, TiO₂ and the like, but is not limited thereto.

It is preferred that the above pattern formation step be performed using a lithography process, a chemical etching method or a physical etching method. Specifically, a pattern is designed at a predetermined location on the substrate at predetermined intervals.

Patterns having various places, intervals, shapes and sizes, particularly patterns having an interval ranging from several tens of nm to several hundreds of μm, a size ranging from several nm to several tens of nm and an area ranging from several μm² to several tens of cm² can be designed depending on the conditions of the lithography process. As such, desired patterns are designed through the lithography process, and are then formed on the substrate through the physical or chemical etching process.

The lithography process is a process of designing desired patterns on a resist material using an electron beam, and the etching process is a process of forming patterns by etching the lower material, such as polymer or inorganic material, using the designed patterns.

The step of growing a zinc oxide layer may be performed using a method selected from among hydro-thermal synthesis, chemical vapor deposition, and physical vapor deposition. In the step of growing a zinc oxide layer, the structure of a zinc oxide microstructure, such as shape, length and diameter, is adjusted using various growth methods, the arrangement thereof, such as location and interval, is adjusted, and thus the zinc oxide microstructure may be selectively grown at the location where the pattern is formed. Specifically, the microstructure that can be formed can be grown in the form of a nanorod, nanoline or nanodisk.

It is preferred that the step of growing a zinc oxide layer using the hydro-thermal synthesis among the growth methods include the steps of (i) preparing a precursor solution by melting a reaction precursor in deionized water, and (ii) heating the precursor solution and the substrate using a reactor. According to an embodiment of the present invention, first, a patterned substrate coated with an organic material or an inorganic material and a nutrient solution containing a reaction precursor having a predetermined concentration is charged into a reactor, and is then heated at a predetermined temperature for a predetermined time to grow a zinc oxide nanostructure. Preferably, the step of heating the nutrient solution and the substrate is performed while the reactor is maintained at a temperature ranging from 30 to 400° C.

More specifically, the kind and form of the microstructure which will be grown can be adjusted by controlling the kind, concentration and reaction temperature of the reaction precursor. The reaction precursor may be a mixture of two or more kinds of precursors, and it is preferred that the hydro-thermal process be performed at one time using the mixture. However, if a nanomaterial having a large length is to be formed, the hydro-thermal process may be performed several times using the mixture. Specifically, it is preferred that a mixture of one or more first reaction precursors selected from the group consisting of zinc acetate, zinc nitrate and zinc and a second reaction precursor selected from the group consisting of hexamethylenetetramine and sodium citrate be used as the reaction precursor. Further, the zinc oxide layer may be formed into a zinc oxide microstructure including different kinds of materials using a mixture including one or more different kinds of reaction precursors selected from the group consisting of Si, Ge, Ce, Cu, W, Ba, Al, In, Cs, Ni, Pt, Mg, Cd, Al, Fe, Ga, Se, Mn, Ti, Ni, N, P, As and C.

For example, in the case where the microstructure is a zinc oxide nanorod, it is preferred that the reactor be adjusted to a temperature ranging from 30 to 400° C., and that zinc nitrate, zinc acetate or derivatives thereof, along with hexamethylenediamine, be used as the reaction precursors. The volume ratio of the zinc nitrate, zinc acetate or derivatives thereof to the hexamethylenediamine in the nutrient solution is adjusted within the range from 10:1 to 1:10, and is preferably 1:1. When the concentration, composition ratio, reaction time and reaction temperature of the nutrient solution are adjusted, it is possible to arbitrarily adjust the aspect ratio of the zinc oxide nanorod. In this case, the aspect ratio of the zinc oxide nanorod can be suitably adjusted according to the required quality level or specifications.

Further, in the case where the microstructure is a zinc oxide nanodisk, it is preferred that the reactor be adjusted to a temperature ranging from 30 to 400° C., and that zinc nitrate, zinc acetate or derivatives thereof and sodium hydroxide (NaOH) and sodium citrate be used as the reaction precursor. The volume ratio of the zinc nitrate, zinc acetate or derivatives thereof to the sodium hydroxide in the nutrient solution is adjusted within the range of 10:1 to 1:10, preferably 1:1. When the concentration, composition ratio, reaction time and reaction temperature of the nutrient solution are adjusted, it is possible to arbitrarily adjust the thickness and width of the zinc oxide nanodisk.

It is preferred that the step of growing a zinc oxide layer using chemical vapor deposition, among the growth methods, include the steps of (i) placing a reaction precursor into a reactor, and (ii) chemically reacting the reaction precursor in the reactor.

More specifically, according to the step of growing a zinc oxide layer using metal organic chemical vapor deposition, among the chemical vapor deposition methods, it is preferred that the patterned substrate coated with an organic material or an inorganic material be charged into a reactor, and that a reaction precursor then be placed into the reactor. Subsequently, a zinc oxide microstructure is grown by chemically reacting the reaction precursor at a predetermined temperature and a predetermined pressure. Diethyl zinc (DEZn), dimethyl zinc (DMZn) or the like is used as the reaction precursor. Further, oxygen (O₂) is used as an oxide source gas, but is not limited thereto. It is preferred that the reactor be adjusted such that the temperature thereof ranges from 200 to 800° C. and the pressure thereof ranges from 10⁻⁵ to 2000 mmHg. Various forms of microstructures, such as nanorods, nanolines and nanowalls, can be formed by adjusting the amount of the reaction precursor, the amount of source gas and the temperature and pressure in the reactor.

It is preferred that the step of growing a zinc oxide layer using physical vapor deposition, among the growth methods, include the steps of (i) charging a substrate including a patterned region into a reactor, and (ii) depositing a reaction precursor on the patterned region using physical vapor deposition, selected from among pulse laser deposition, electron beam epitaxy, and chemical beam epitaxy. It is further preferred that the step of depositing a reaction precursor be performed while the reactor is maintained at a temperature ranging from 200 to 800° C.

More specifically, according to the step of growing a zinc oxide layer using PLD, MBE or electron beam evaporation, among the physical vapor deposition methods, first, the substrate coated with an organic material or an inorganic material and patterned in a desired shape is charged into a reactor, and then elements or molecules of a zinc oxide target discharged from a target are deposited on the substrate by heating the target using a laser or an electron beam. Subsequently, the substrate deposited with zinc oxide is taken out of the reactor, and then passes through a lift off process to selectively grow a zinc oxide microstructure.

According to another aspect of the present invention, there is provided a zinc oxide microstructure prepared by the above method, more particularly a zinc oxide microstructure including (i) a substrate; (ii) an organic material layer or an inorganic material layer located on the substrate and including a patterned region; and (iii) a zinc oxide layer selectively grown only on the patterned region.

According to a preferred embodiment, there is provided a zinc oxide microstructure including (i) a substrate; (ii) a buffer layer grown on the substrate; (iii) an organic material layer or an inorganic material layer located on the buffer layer and including a patterned region; and (iv) a zinc oxide layer selectively grown only on the patterned region.

It is preferred that the difference of lattice constant between the buffer layer and the zinc oxide layer is 20% or less, and that the buffer layer have a thickness of at least 10˜200 nm. More preferably, the buffer layer is selected from the group consisting of a GaN film, a ZnO film and a combination film thereof.

The constituent, form and the like of the organic material, inorganic material or zinc oxide layer in the method of preparing the zinc oxide microstructure according to the present invention may be directly applied to the constituent, form and the like of the organic material, inorganic material or zinc oxide layer in the zinc oxide microstructure of the present invention. Particularly, it is preferred that the zinc oxide layer have a diameter ranging from 10 nm to 10 μm, a thickness ranging from 10 nm to 10 μm, and a length of 1 to 100 μm.

Further, the zinc oxide layer may additionally include one or more different kinds of materials selected from the group consisting of Si, Ge, Ce, Cu, W, Ba, Al, In, Cs, Ni, Pt, Mg, Cd, Al, Fe, Ga, Se, Mn, Ti, Ni, N, P, As and C.

In the specification, the description “a layer is located on another layer” means either that a layer may be located directly on another layer, or that another layer may be interposed therebetween. Further, the thickness and size of each layer shown in the drawings are exaggeratedly represented for the purpose of the ease and clarity of explanation. In the drawings, the same reference numerals are used throughout the different drawings to designate the same components.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a scanning electron microscope photograph showing zinc oxide nanorods prepared using hydro-thermal synthesis;

FIGS. 2 and 3 are scanning electron microscope photographs showing zinc oxide nanorods selectively grown on a substrate according to preferred embodiments of the present invention;

FIGS. 4 to 7 are views explaining the zinc oxide nanorods and the preparation method thereof according to preferred embodiments of the present invention;

FIGS. 8A to 8C are graphs showing X-ray 2θ/θ scan curves and X-ray θ scan curves measured using X-ray Diffraction (XRD) to analyze the crystallinity of the selectively grown zinc oxide nanorods; and

FIGS. 9A to 9C are graphs showing results measured using photoluminescence to analyze the optical characteristics of the selectively grown zinc oxide nanorods.

### DETAILED DESCRIPTION OF SPECIFIC EMBODIMENTS

Hereinafter, the present invention will be described in detail with reference to the following examples. Since the present invention can be easily modified to have other forms by those skilled in the art, the scope of the invention is not limited to the following examples.

### Example 1

In Example 1, an epitaxy gallium nitride buffer layer was obtained by being deposited on a substrate, such as Si, Al₂O₃, GaN, GaAs, ZnO, InP, SiC, glass (pyrex glass or tin oxide glass) or the like, using metal organic chemical vapor deposition (MOCVD), molecular beam epitaxy (MBE), or hydride vapor phase epitaxy (HVPE).

In the present invention, a gallium nitride substrate was used as a substrate and was cleaned through the following cleaning process. First, the substrate was cleaned using acetone in an ultrasonic bath and was then cleaned using methanol again. Organic material on the substrate was removed through the cleaning process.

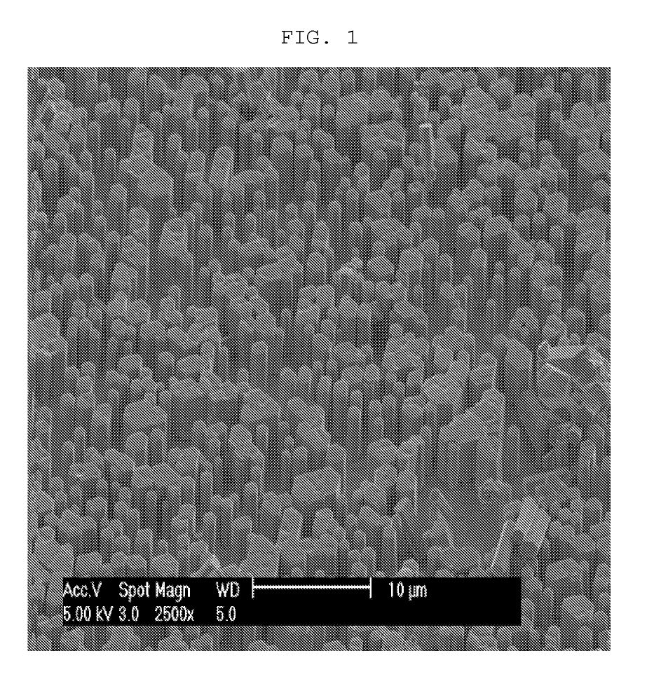

After a PMMA pattern was formed on the substrate, a nutrient solution for growing zinc oxide nanorods was prepared. Specifically, the process of preparing the nutrient solution was as follows. First, a first solution was prepared by dissolving 0.1 M of zinc nitrate in 50 mL of deionized water. Then, a second solution was prepared by dissolving 0.1 M of hexamethylenetetraamine in 50 mL of deionized water. Then, a mixed solution having a total volume of 100 mL was prepared by mixing the first solution with the second solution. In this case, the mixed solution was adjusted such that the pH thereof was 7.0. This mixed solution was placed into a Teflon autoclave, and then the patterned substrate was placed at the bottom of the Teflon autoclave at a temperature of 95° C. for 6 hours to grow zinc oxide nanorods. Subsequently, the substrate was cleaned using the deionized water. The obtained zinc oxide nanorods had an average length of 3 μm and an average diameter of 2 μm, as shown in the scanning electron microscope photograph of FIG. 1. The zinc oxide nanorods may be variously prepared such that the length and diameter thereof are 1˜3 μm, 100 nm˜10 μm, respectively, depending on the growth conditions, such as growth time, temperature, or the concentration of reactant.

### Example 2

In Example 2, unlike Example 1, selectively grown zinc oxide nanorods were prepared by forming a pattern on a gallium nitride substrate. The method of preparing a PMMA solution, which is the polymer material that will be applied on the gallium nitride substrate, was as follows. Here, PMMA, which is sold by chemical companies, may be used without diluting it, and its concentration may be adjusted using a polymer diluent according to the desired form of the pattern. This fact becomes a significant factor in the determination of subsequent process conditions such as the thickness of the coating layer etc.

The PMMA solution obtained through the method was applied on the gallium nitride substrate (for example, a gallium nitride substrate which is sliced along (0001) plane) using a dip coater, a spin coater or the like. More specifically, the PMMA solution was dropped onto the substrate using a spuit, and was then applied on the substrate using the spin coater at a rotation speed of 1000˜5000 rpm for 5˜30 sec. The thickness of the PMMA coating layer could be adjusted by controlling the coating time and the coating number using the above method.

After the PMMA solution was applied on the substrate, the coated substrate was pre-baked using a hot plate or a conventional oven. The pre-baking process was performed at a temperature of 180° C. for 90 sec or at a temperature of 170° C. for 30 minutes.

Subsequently, a pattern having a desired size and a desired interval was formed on the pre-baked substrate using an electron beam lithography apparatus, and the pattern was formed at suitable locations. Then, the substrate, on which the pattern was designed, was placed into a mixed solution of methylisobutylketone (MIBK) and isopropylalcohol (IPA), which was a developer, for 1 minute, and the portion thereof exposed to an electron beam was removed, thereby substantially obtaining a pattern. Further, oxygen plasma treatment was performed for 10˜30 sec in order to completely remove the PMMA remaining at the bottom portion of the pattern.

In the electron lithography process, the size, interval and total area of the pattern are designed using a CAD program. The size and interval of the pattern can be determined in units of a micrometer or less, and the total area thereof can be adjusted in units of several hundred micrometers. Further, the size, interval and total area of the substantial pattern are determined depending on the electron beam energy, current, exposure amount (dose) and exposure time. Further, the current and the exposure amount change depending on the size and interval of the pattern, the thickness of the PMMA coating layer, and the kind of substrate, and thus the pattern is written. Here, a current of 10˜50 pA was used as the current, and the exposure amount was adjusted to be within the range of 200˜400 μC/cm².

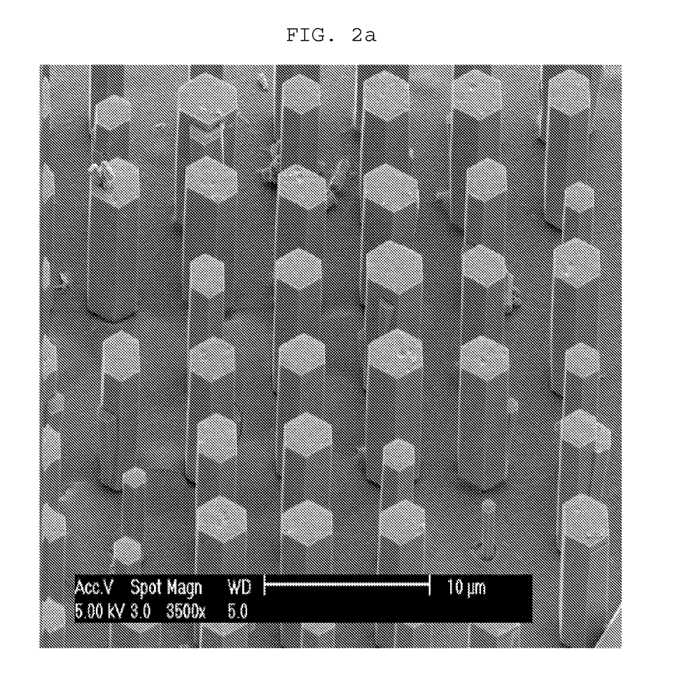

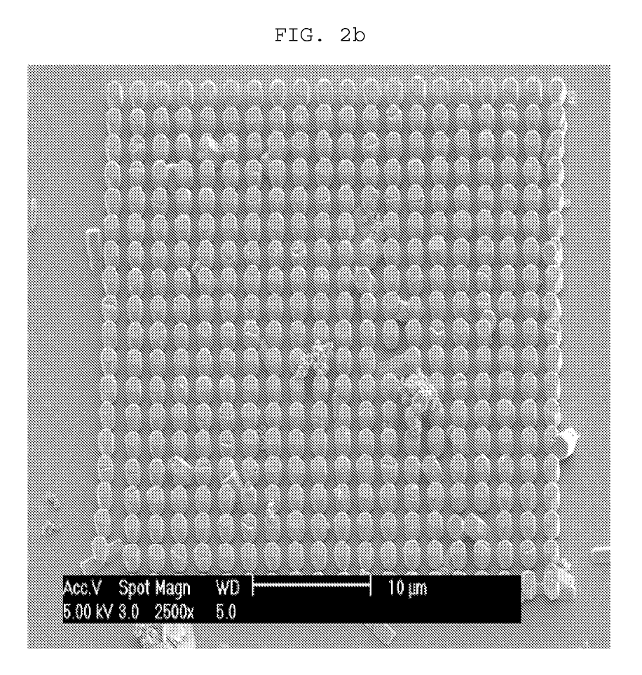

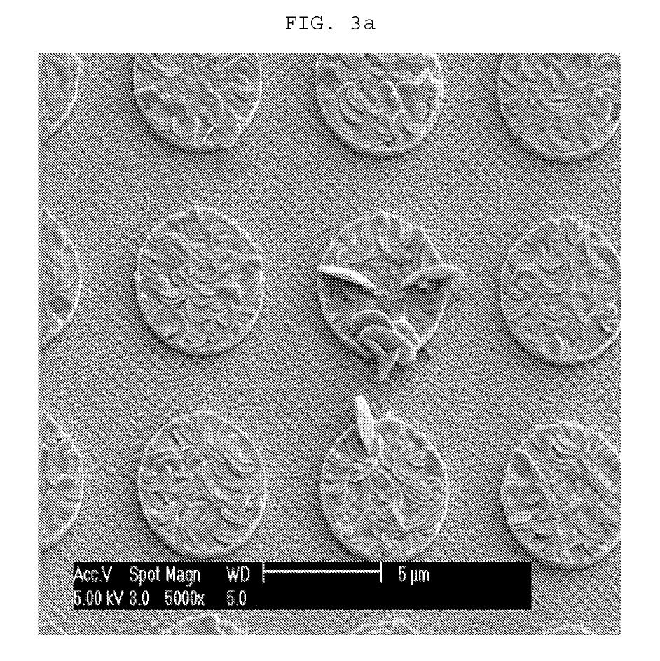

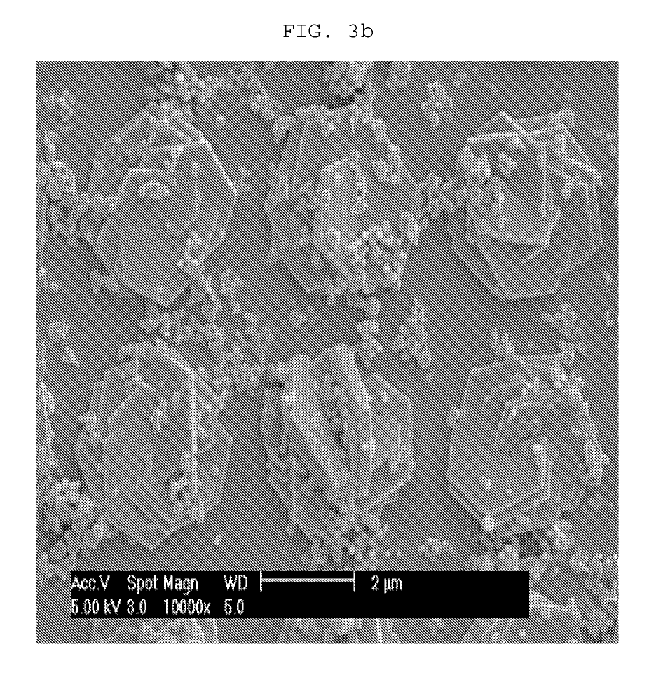

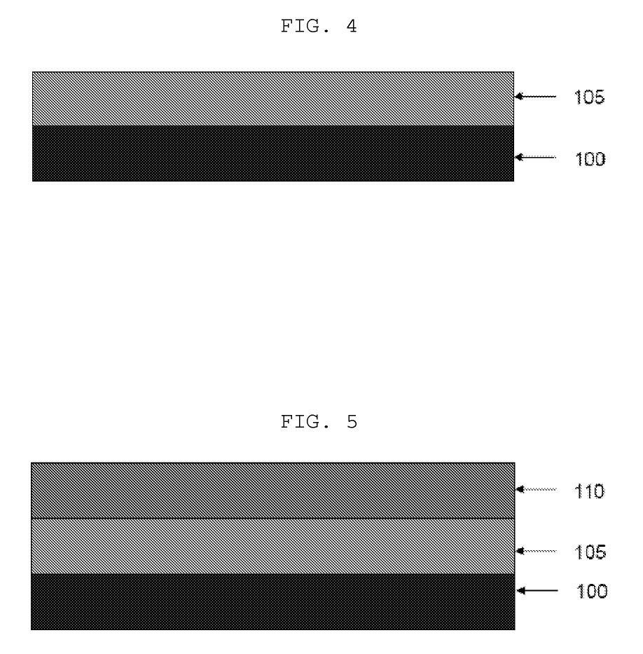

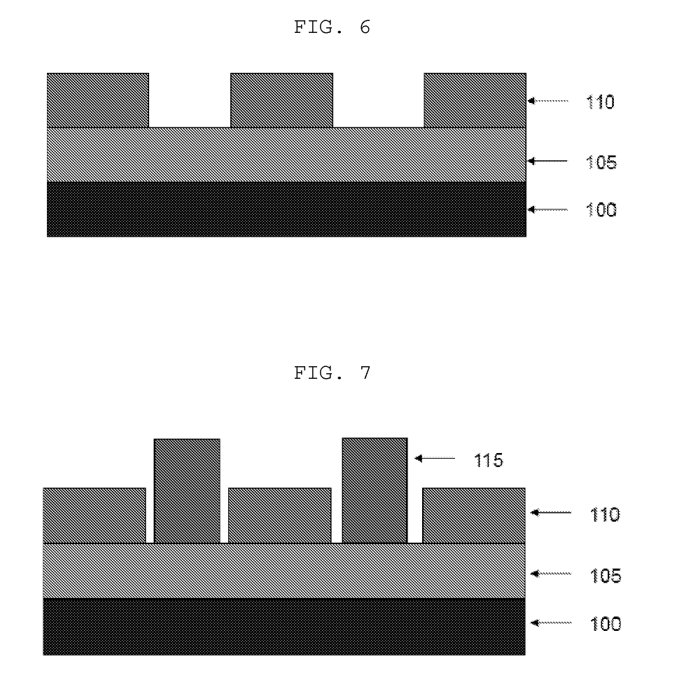

After a PMMA pattern was formed on the substrate, as in Example 1, a nutrient solution was prepared to grow zinc oxide nanorods. The obtained zinc oxide nanorods had an average length of 7 μm and an average diameter of 2 μm, as shown in the scanning electron microscope photograph of FIG. 2A. The zinc oxide nanorods may be variously prepared such that the length and diameter thereof are 1˜3 μm, 100 nm˜10 μm, respectively, depending on growth conditions such as growth time, temperature, and concentration of reactant.

### Example 3

In Example 3, similar to Example 1, a zinc oxide buffer layer was formed on a silicon substrate. An epitaxy zinc oxide buffer layer was obtained by being deposited on a substrate, such as Si, Al₂O₃, GaN, GaAs, ZnO, InP, SiC, glass (pyrex glass or tin oxide glass), polymer (PET, PP) or the like, using metal organic chemical vapor deposition (MOCVD), molecular beam epitaxy (MBE), pulse laser deposition (PLD), electron beam evaporation, or the Like.

After the zinc oxide buffer layer was formed, as in Example 1, PMMA was applied on the zinc oxide buffer layer, a pattern was formed on the silicon substrate using electron beam lithography, and then zinc oxide nanorods were grown only on the patterned portion of the substrate. The obtained zinc oxide nanorods had an average length of 1 μm and an average diameter of 1 μm, as shown in the scanning electron microscope photograph of FIG. 2B.

### Example 4

In Example 4, as in Example 2, a zinc oxide buffer layer was formed on a silicon substrate. An epitaxy zinc oxide buffer layer was obtained by being deposited on a substrate, such as Si, Al₂O₃, GaN, GaAs, ZnO, InP, SiC, glass (pyrex glass or tin oxide glass), polymer (PET or PP) or the like, using metal organic chemical vapor deposition (MOCVD), molecular beam epitaxy (MBE), pulse laser deposition (PLD), electron beam evaporation, or the like.

After the zinc oxide buffer layer was formed, as in Example 2, PMMA was applied on the zinc oxide buffer layer, and then a pattern was formed on the silicon substrate using electron beam lithography. After a PMMA pattern was formed on the substrate, a nutrient solution for growing zinc oxide nanodisks was prepared. Specifically, the process of preparing the nutrient solution was as follows. First, a first solution was prepared by dissolving 0.1 M of zinc acetate in 50 mL of deionized water. Then, a second solution was prepared by dissolving 0.1 M of sodium citrate in 50 mL of deionized water. Then, a mixed solution having a total volume of 100 mL was prepared by mixing the first solution with the second solution. Subsequently, the mixed solution was adjusted such that the pH thereof is 7.0. This mixed solution was placed into a Teflon autoclave, and then the patterned substrate was placed at the bottom of the Teflon autoclave at a temperature of 95° C. for 12 hours to grow zinc oxide nanorods. After that, the substrate was cleaned using the deionized water. The obtained zinc oxide nanorods had an average diameter of 5 μm and an average thickness of 500 nm, as shown in the scanning electron microscope photograph of FIG. 3A. The zinc oxide nanodisks may be variously prepared, such that the diameter and thickness thereof are 100 nm˜10 μm, 10 nm˜1 μm, respectively, depending on growth conditions such as growth time, temperature, or concentration of reactant.

### Example 5

In Example 5, similar to Example 4, a gallium nitride buffer layer was formed on a silicon substrate. An epitaxy gallium nitride buffer layer was obtained by being deposited on a substrate, such as Si, Al₂O₃, GaN, GaAs, ZnO, InP, SiC or the like, using metal organic chemical vapor deposition (MOCVD), molecular beam epitaxy (MBE), pulse laser deposition (PLD), electron beam evaporation, or the like.

After the gallium nitride buffer layer was formed, as in Example 4, PMMA was applied on the gallium nitride buffer layer, a pattern was formed on the silicon substrate using electron beam lithography, and then zinc oxide nanodisks were grown only on the patterned portion of the substrate. The obtained zinc oxide nanodisk array had an average diameter of 5 μm and an average thickness of 500 nm, as shown in the scanning electron microscope photograph of FIG. 3B. The zinc oxide nanodisks could be variously prepared such that the diameter and thickness thereof were 100 nm˜10 μm and 10 nm˜1 μm, respectively, depending on growth conditions such as growth time, temperature, or the concentration of the reactant.

### Experimental Example 1

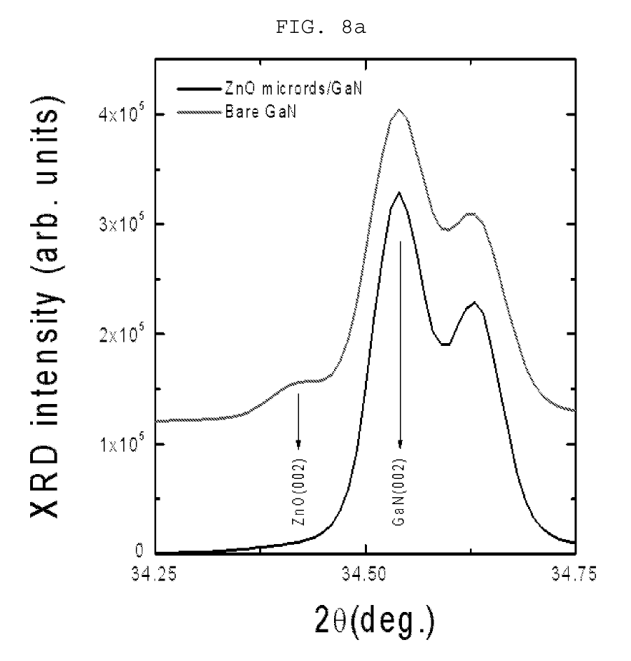

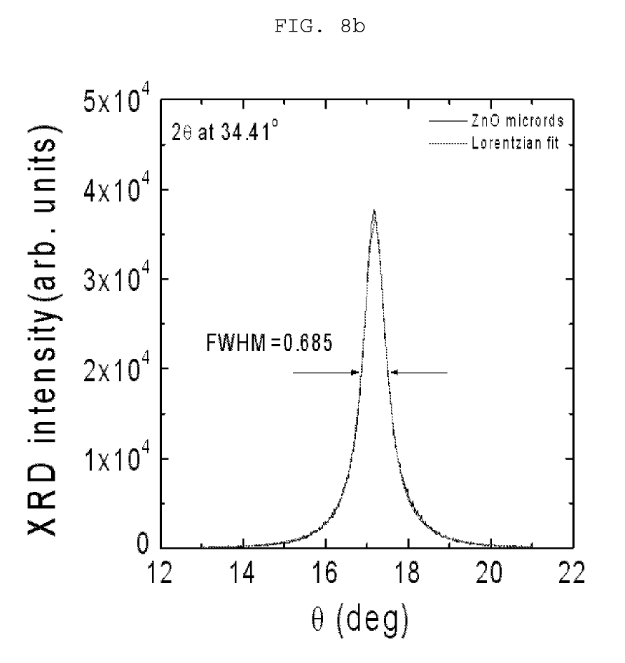

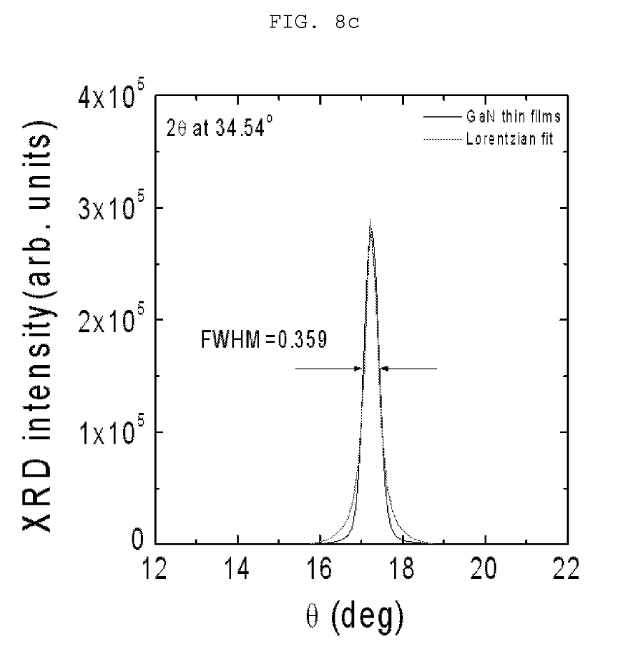

FIGS. 8A to 8C are graphs showing X-ray 2θ/θ scan curves and X-ray θ scan curves measured using X-ray Diffraction (XRD) to analyze the crystallinity of selectively grown zinc oxide nanorod arrays. X-ray Diffraction (hereinafter, referred to as ‘XRD’) is used to analyze the crystallographic structure of thin films through diffraction peaks. The crystallinity analysis can be carried out by measuring the X-ray 2θ/θ scan curve and the X-ray θ scan curve. FIG. 8A is a graph showing XRD 2θ/θ scan curves in the case where a gallium nitride buffer layer is grown on a sapphire substrate and zinc oxide nanorods are grown on the sapphire substrate on which the gallium nitride buffer layer is located. FIGS. 8B and 8C are graphs showing XRD rocking curves in the case where zinc oxide nanorods are grown on the gallium nitride buffer layer in Example 2, described above.

Referring to FIG. 8A, it was found that the zinc oxide nanorods grown on the gallium nitride buffer layer grew in the [002] direction. That is, it was found that the zinc oxide nanorods grew in a direction perpendicular to the substrate, as shown in the scanning electron microscope photography.

Referring to FIGS. 8B and 8C, it was found that the full width at half maximum (FWHM) in the XRD rocking curve of GaN thin film grown on a sapphire substrate was 0.359°, and that the full width at half maximum (FWHM) in the XRD rocking curve of zinc oxide nanorods was 0.685°. As such, since the full width at half maximum (FWHM) in the XRD rocking curve of the GaN thin film and that of the zinc oxide nanorods are smaller than that of nanorods prepared using other growth methods, it was found that the GaN thin film and the zinc oxide nanorods had very excellent crystallinity.

### Experimental Example 2

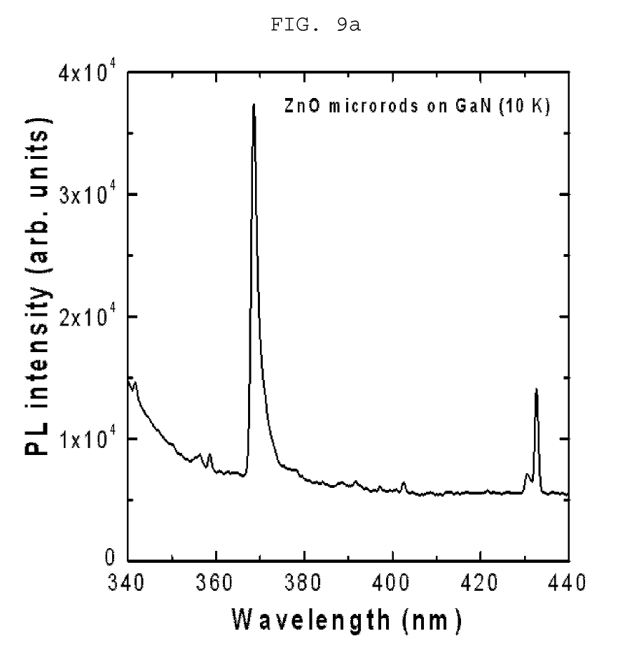

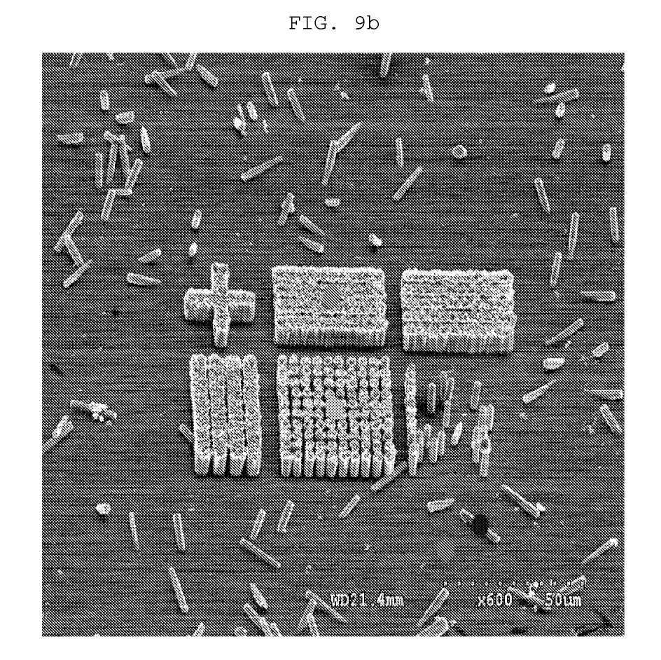

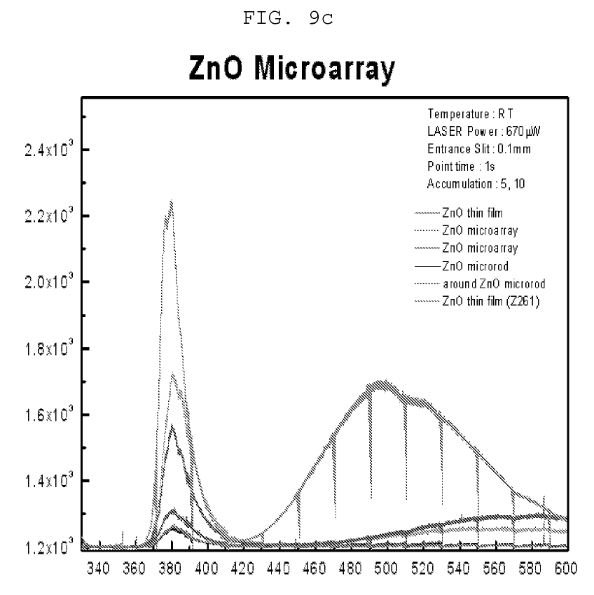

FIGS. 9A to 9C are graphs showing results measured using photoluminescence (hereinafter, referred to as ‘PL’) at a low temperature (10K) to analyze the optical characteristics of the selectively grown zinc oxide nanorod arrays. In the PL measurement, the characteristics thereof were measured using a He—Cd laser having a wavelength of 325 nm as a light source, and were evaluated through the recombination of electrons and holes in bandgaps. FIG. 9A shows PL peaks of the zinc oxide nanorod array grown on the gallium nitride substrate in Example 1 described above.

FIG. 9A shows the PL peak of the gallium nitride thin film and the PL peak of the zinc oxide nanorods grown on the gallium nitride substrate, as determined through PL measurement at a low temperature (10K).

FIG. 9C shows PL peaks of the zinc oxide nanorod array selectively grown on the substrate on which a zinc oxide buffer layer was deposited in Example 3 described above. FIG. 9C shows the PL peak of the selectively grown zinc oxide nanorods as determined through PL measurement at room temperature (298K). Thus, it was found that the optical characteristics of the zinc oxide nanorods were excellent.

According to the method of selectively growing a microstructure of the present invention, there is provided a method of preparing a microstructure including the steps of coating a substrate with an organic material or an inorganic material; forming a pattern on the substrate at a desired location and a desired interval using a physical or chemical etching method; and selectively growing zinc oxide microstructures on the location where the pattern is formed by adjusting the structure, such as the shape, diameter and length thereof, and adjusting a spatial arrangement, such as the locations and intervals therebetween. In the present invention, compared to the conventional method of selectively growing a microstructure, a process thereof is relatively simple, it is possible to ensure the selective growth of the nanomaterial to realize a desired shape, length and diameter at a desired location over a large area, at a desired interval, and at a low temperature, and thus a semiconductor device can be easily manufactured using the microstructure.

Although the preferred embodiments of the present invention, described above, have been disclosed for illustrative purposes, those skilled in the art will appreciate that various modifications, additions and substitutions are possible, without departing from the scope and spirit of the invention as disclosed in the accompanying claims.

What is claimed is:

1. A method of preparing zinc oxide microstructures, comprising the steps of:
(a) applying an organic material or an inorganic material on a substrate;
(b) forming a patterned region on the substrate by patterning a layer coated with the organic material or the inorganic material using a lithography process and a physical or chemical etching method; and
(c) selectively growing a zinc oxide layer on the patterned regions.

2. A method of preparing zinc oxide microstructures, comprising the steps of:
(a) growing a buffer layer on a substrate;
(b) applying an organic material or an inorganic material on the buffer layer;
(c) forming a patterned region on the buffer layer by patterning a layer coated with the organic material or the inorganic material using a lithography process and a physical or chemical etching method; and
(d) selectively growing a zinc oxide layer on the patterned region.

3. The method of preparing zinc oxide microstructures according to claim 2, wherein a difference of a lattice constant between the buffer layer and the zinc oxide layer is 20% or less, and the buffer layer has a thickness of at least 10˜200 nm.

4. The method of preparing zinc oxide microstructures according to claim 3, wherein the buffer layer is selected from the group consisting of a GaN film, a ZnO film and a combination film thereof.

5. The method of preparing zinc oxide microstructures according to claim 1 or 2, wherein the substrate is selected from the group consisting of Si, Al₂O₃, GaN, GaAs, ZnO, InP, SiC, glass and polymer.

6. The method of preparing zinc oxide microstructures according to claim 1 or 2, wherein the organic material is selected from the group consisting of a photoresist material, an electron beam resist material and a polymeric material, and the inorganic material is selected from the group consisting of a ceramic material and a semiconductor material.

7. The method of preparing zinc oxide microstructures according to claim 6, wherein the electron beam material is selected from the group consisting of PMMA and poly(butene-1-sulphone).

8. The method of preparing zinc oxide microstructures according to claim 1 or 2, wherein the zinc oxide layer additionally comprises one or more different materials selected from the group consisting of Si, Ge, Ce, Cu, W, Ba, Al, In, Cs, Ni, Pt, Mg, Cd, Al, Fe, Ga, Se, Mn, Ti, Ni, N, P, As and C.

9. The method of preparing zinc oxide microstructures according to claim 1 or 2, wherein the step of forming patterned regions is performed using a lithography process and a chemical or physical etching method.

10. The method of preparing zinc oxide microstructures according to claim 1 or 2, wherein the step of growing zinc oxide layers is performed using a method selected from hydro-thermal synthesis, chemical vapor deposition and physical vapor deposition.

11. The method of preparing zinc oxide microstructures according to claim 10, wherein the step of growing a zinc oxide layer using the hydro-thermal synthesis comprises the steps of preparing a precursor solution by melting a reaction precursor in deionized water, and heating the precursor solution and the substrate in a reactor.

12. The method of preparing zinc oxide microstructures according to claim 11, wherein the reaction precursor is a mixture of two or more precursors.

13. The method of preparing zinc oxide microstructures according to claim 12, wherein the reaction precursor is a mixture of one or more first reaction precursors selected from the group consisting of zinc acetate, zinc nitrate and zinc and a second reaction precursor selected from the group consisting of hexamethylenetetramine and sodium citrate.

14. The method of preparing zinc oxide microstructures according to claim 13, wherein the mixture additionally comprises one or more different reaction precursors selected from the group consisting of Si, Ge, Ce, Cu, W, Ba, Al, In, Cs, Ni, Pt, Mg, Cd, Al, Fe, Ga, Se, Mn, Ti, Ni, N, P, As and C.

15. The method of preparing zinc oxide microstructures according to claim 11, wherein the step of heating the precursor solution and the substrate using a reactor is performed while the reactor is maintained at a temperature of 30 to 400° C.

16. The method of preparing zinc oxide microstructures according to claim 10, wherein the step of growing a zinc oxide layer using the chemical vapor deposition comprises the steps of placing a reaction precursor into a reactor, and chemically reacting the reaction precursor in the reactor.

17. The method of preparing zinc oxide microstructures according to claim 15, wherein the reaction precursor is a mixture of two or more reaction precursors, and the two or more reaction precursors are placed into the reactor through an additional line.

18. The method of preparing zinc oxide microstructures according to claim 16, wherein the reaction precursor uses one selected from the group consisting of diethylamine (DEZn) and dimethylamine (DMZn) as a first reaction precursor, and uses oxygen (O₂) as a second reaction precursor.

19. The method of preparing zinc oxide microstructures according to claim 16, wherein the step of chemically reacting the reaction precursor in the reactor is performed while the reactor is maintained at a temperature of 200 to 800° C.

20. The method of preparing zinc oxide microstructures according to claim 10, wherein the step of growing a zinc oxide layer using the physical vapor deposition comprises the steps of charging a substrate including a patterned region into a reactor, and depositing a reaction precursor on the patterned region using a physical vapor deposition method selected from the group consisting of pulse laser deposition, electron beam epitaxy, and chemical beam epitaxy.

21. The method of preparing zinc oxide microstructures according to claim 20, wherein the step of depositing a reaction precursor is performed while the reactor is maintained at a temperature of 200 to 800° C.

22. The method of preparing zinc oxide microstructures according to claim 1 or 2, wherein the zinc oxide layer has a different shape, diameter and length, depending on growth conditions in the step of growing the zinc oxide layer

23. A zinc oxide microstructure, comprising:
a substrate;
an organic material layer or an inorganic material layer located on the substrate and including a patterned region; and
a zinc oxide layer selectively grown only on the patterned region.

24. A zinc oxide microstructure, comprising:
a substrate;
a buffer layer grown on the substrate;
an organic material layer or an inorganic material layer located on the buffer layer and including a patterned region; and
a zinc oxide layer selectively grown only on the patterned region.

25. The zinc oxide microstructure according to claim 24, wherein a difference of lattice constant between the buffer layer and the zinc oxide layer is 20% or less, and the buffer layer has a thickness of at least 10˜200 nm.

26. The zinc oxide microstructure according to claim 25, wherein the buffer layer is selected from the group consisting of a GaN film, a ZnO film and a combination film thereof.

27. The zinc oxide microstructure according to claim 23 or 24, wherein the substrate is selected from the group consisting of Si, Al₂O₃, GaN, GaAs, ZnO, InP, SiC, glass and polymer.

28. The zinc oxide microstructure according to claim 27, wherein the glass is pyrex glass or tin oxide glass, and the polymer is polyethyleneterephthalate (PET) or polypropylene (PP).

29. The zinc oxide microstructure according to claim 23 or 24, wherein the organic material is selected from the group consisting of a photoresist material, an electron beam resist material and a polymeric material, and the inorganic material is selected from the group consisting of a ceramic material and a semiconductor material.

30. The zinc oxide microstructure according to claim 29, wherein the electron beam material is selected from the group consisting of PMMA and poly(butene-1-sulphone).

31. The zinc oxide microstructure according to claim 23 or 24, wherein the zinc oxide layer additionally comprises one or more different kinds of materials selected from the group consisting of Si, Ge, Ce, Cu, W, Ba, Al, In, Cs, Ni, Pt, Mg, Cd, Al, Fe, Ga, Se, Mn, Ti, Ni, N, P, As and C.

32. The zinc oxide microstructure according to claim 23 or 24, wherein the zinc oxide layer has a diameter of 10 nm to 10 μm, a thickness of 10 nm to 10 μm and a length of 1 to 100 μm.
